(19) United States
(12) Patent Application Publication
(10) Pub. No.: US 2013/0195676 A1
(43) Pub. Date: Aug. 1, 2013

(54) FAN CONTROLLING METHOD AND ELECTRONIC DEVICE

(71) Applicants: Zheng-Hong Luo, Taipei City (TW); Meng-Hsiung Lee, Taipei City (TW); Da-Li Lai, Taipei City (TW); Pai-Ching Huang, Taipei City (TW); Hsin-Yi Lee, Taipei City (TW)

(72) Inventors: Zheng-Hong Luo, Taipei City (TW); Meng-Hsiung Lee, Taipei City (TW); Da-Li Lai, Taipei City (TW); Pai-Ching Huang, Taipei City (TW); Hsin-Yi Lee, Taipei City (TW)

(73) Assignee: Asustek Computer Inc., Taipei City (TW)

(21) Appl. No.: 13/751,154

(22) Filed: Jan. 28, 2013

Related U.S. Application Data
(60) Provisional application No. 61/592,005, filed on Jan. 30, 2012.

(30) Foreign Application Priority Data
Dec. 18, 2012 (TW) 101148147

(51) Int. Cl. H05K 7/20

(52) U.S. Cl. CPC H05K 7/20209
USPC 417/44.1; 361/695

(57) ABSTRACT

A fan controlling method for an electronic device having at least one fan is provided. In the method, as for each of the fans, a calibration process is performed to obtain fan rotation information and an power/fan-rotation speed information. An assembling position of each of the fans within the electronic device is determined and an operation mode of the electronic device is determined as well. As for each of the fans, according to the fan rotation information, an power/fan-rotation speed information, the assembling position and the operation mode, a temperature-power correlation between the operation temperature of the processor and the power of the fan is calculated. According to the temperature-power correlation of each of the fans, the fans within the electronic device are controlled respectively.

### CROSS-REFERENCE TO RELATED APPLICATION

This application claims the priority benefit of U.S.A. provisional application Ser. No. 61/592,005, filed on Jan. 30, 2012 and Taiwan application serial no. 101148147, filed on Dec. 18, 2012. The entirety of each of the above-mentioned patent applications is hereby incorporated by reference herein and made a part of specification.

### BACKGROUND OF THE INVENTION

1. Field of Invention

The present invention relates to a controlling method and an electronic device. More particularly, the present disclosure relates to a fan controlling method and an electronic device equipped with fans.

2. Description of Related Art

Conventionally, the heat dissipation fans assembled in most of the electronic devices are set to be rotating at the full speed mode while the electronic device is operated. Some of the electronic devices provide three-step modulation or four-step modulation of fan rotation speed for the user to adjust the fan rotation speed with the change of the operation temperature of the electronic device. Moreover, in some rare situations, the user can manually adjust the rotation speed of each of the fans in the electronic device.

However, different fan product brands, different fan functions and different fan assembling positions lead to different heat dissipation efficiencies of different fans. That is, under the affection including the operation features of the fans and the external assembling positions, the fans respectively have correlation lines of the fan rotation speed versus temperature which are different from each other. Therefore, the aforementioned full speed mode, three-step modulation mode, four-step modulation mode or user manually adjustment cannot optimize the ratio of the power consumption to the heat dissipation efficiency. Accordingly, the power of the electronic device is consumed.

### SUMMARY OF THE INVENTION

The present disclosure is to provide a fan controlling method capable of intelligently controlling the fan cluster in the electronic device to prove adequate heat dissipation function and to decrease the power consumption.

The invention provides a fan controlling method for an electronic device. In the method, for each of the fan, a calibration process is performed to obtain fan rotation information and a power/fan-rotation speed information of the fan. An assembling position of each of the fans in the electronic device is determined. An operation mode of the electronic device is determined. For each of the fans, according to the fan rotation information, the power/fan-rotation speed information, the assembling position and the operation mode, a temperature-power correlation between an operation temperature of the processor and a power of the fan is calculated. According to the temperature-power correlation of each of the fans, the fans are controlled at an operation status of the electronic device.

According to one embodiment of the present disclosure, the step of determining the assembling position of each of the fans in the electronic device comprises receiving a setting signal to set the assembling position of each of the fans in the electronic device.

According to one embodiment of the present disclosure, the operation mode includes a standard mode, a silence mode or a high-efficiency mode.

According to one embodiment of the present disclosure, the temperature-power correlation corresponding to each of the fans is a slope discontinuous correlation line of the power of the fan versus the operation temperature of the processor and the discontinuous correlation line comprises at least a slope turning point.

According to one embodiment of the present disclosure, the at least slope turning point in the discontinuous slope correlation line respectively corresponding to each of the fans represents a correlation between the power of the fan and the operation temperature of the processor while an operation efficiency of the processor is 50%.

According to one embodiment of the present disclosure, the fan controlling method further comprises modifying the operation mode of the electronic device. For each of the fans, according to the rotation information of the fan, the power/fan-rotation speed information, the assembling position of the fan and the modified operation mode, the temperature-power correlation is re-calculated. According to each of the temperature-power correlations, each of the fans is controlled.

According to one embodiment of the present disclosure, the fan controlling method further comprises changing the assembling position of at least one of the fans. The calibration process is re-performed to obtain the fan rotation information and the power/fan-rotation speed information of each of the fans after the assembling position of the at least one of the fans is changed. For each of the fans, according to the rotation information of the fan and the power/fan-rotation speed information of the fan, the changed assembling position of the fan and the operation mode, the temperature-power correlation re-calculated. According to each of the temperature-power correlations, each of the fans is controlled.

According to one embodiment of the present disclosure, the step of changing the assembling position of at least one of the fans comprises removing at least one of the fans or replacing at least one of the fans.

According to one embodiment of the present disclosure, the fan rotation information of each of the fans includes a rotation-starting-point power of the fan, a starting-point-rotation speed of the fan and a stop-point power of the fan.

The invention further provides an electronic device comprising a storage device, at least one fan and a processor. The storage device stores a computer readable and writable program. The processor is coupled to the fans and the storage device and executes a plurality of instructions of the computer readable and writable program. The instructions comprise performing a calibration process to obtain fan rotation information and an power/fan-rotation speed information of the fan. An assembling position of each of the fans in the electronic device is determined. An operation mode of the electronic device is determined. For each of the fans, according to the fan rotation information, the power/fan-rotation speed information, the assembling position and the operation mode, a temperature-power correlation between an operation temperature of the processor and a power of the fan is calculated. According to the temperature-power correlation of each of the fans, the fans are controlled at an operation status of the electronic device.

According to one embodiment of the present disclosure, the instruction of reading the assembling position of each of the fans in the electronic device comprises: receiving a setting signal to set the assembling position of each of the fans in the electronic device.

According to one embodiment of the present disclosure, the operation mode includes a standard mode, a silence mode or a high-efficiency mode.

According to one embodiment of the present disclosure, the temperature-power correlation corresponding to each of the fans is a slope discontinuous correlation line of the power of the fan versus the operation temperature of the processor and the discontinuous correlation line comprises at least a slope turning point.

According to one embodiment of the present disclosure, the at least slope turning point in the discontinuous slope correlation line respectively corresponding to each of the fans represents a correlation between the power of the fan and the operation temperature of the processor while an operation efficiency of the processor is 50%.

According to one embodiment of the present disclosure, the instructions further comprise modifying the operation mode of the electronic device. For each of the fans, according to the rotation information of the fan, the power/fan-rotation speed information, the assembling position of the fan and the modified operation mode, the temperature-power correlation is re-calculated. According to each of the temperature-power correlations, each of the fans is controlled.

According to one embodiment of the present disclosure, the instructions further comprise changing the assembling position of at least one of the fans. The calibration process is re-performed to obtain the fan rotation information and the power/fan-rotation speed information of each of the fans after the assembling position of the at least one of the fans is changed. For each of the fans, according to the rotation information of the fan and the power/fan-rotation speed information of the fan, the changed assembling position of the fan and the operation mode, the temperature-power correlation is re-calculated. According to each of the temperature-power correlations, each of the fans is controlled.

According to one embodiment of the present disclosure, the instruction of changing the assembling position of at least one of the fans comprises removing at least one of the fans or replacing at least one of the fans.

According to one embodiment of the present disclosure, the fan rotation information of each of the fans includes a rotation-starting-point power of the fan, a starting-point-rotation speed of the fan and a stop-point power of the fan.

In the present disclosure, each of the fans in the fan cluster are calibrated to obtain the fan individual operation feature (including fan rotation information and the power/fan-rotation speed information of the fan). Furthermore, by further taking the assembling position of each of the fans and the user preferred operation mode of the electronic device into account, the temperature-power correlation between the temperature of the processor and the power of each of the fans. According to the temperature-power correlation of each of the fans, the rotation status of each of the fans in the fan cluster is intelligently adjusted to provide the most adequate heat dissipation efficiency and the best power utilization while the electronic device is at the operation status. Therefore, the efficiency of the fan cluster is increased and the power consumption of the electronic device is decreased.

It is to be understood that both the foregoing general description and the following detailed description are exemplary, and are intended to provide further explanation of the invention as claimed.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 is a flow chart showing a fan controlling method according to one embodiment of the present disclosure.

FIG. 2 is a correlation table showing power/fan-rotation speed information obtained from a calibration process according to one embodiment of the present disclosure.

FIG. 3 is a schematic diagram showing assembling positions of fans in the electronic device.

FIG. 4 is a plot line diagram showing a temperature-power correlation between the power of a single fan and the operation temperature of the processor according to one embodiment of the present disclosure.

FIG. 5 is a flow chart illustrating a fan controlling method according to another embodiment of the present disclosure.

FIG. 6 is a flow chart illustrating a fan controlling method according to the other embodiment of the present disclosure.

FIG. 7 is a schematic diagram showing an electronic device according to one embodiment of the present disclosure.

### DESCRIPTION OF THE PREFERRED EMBODIMENTS

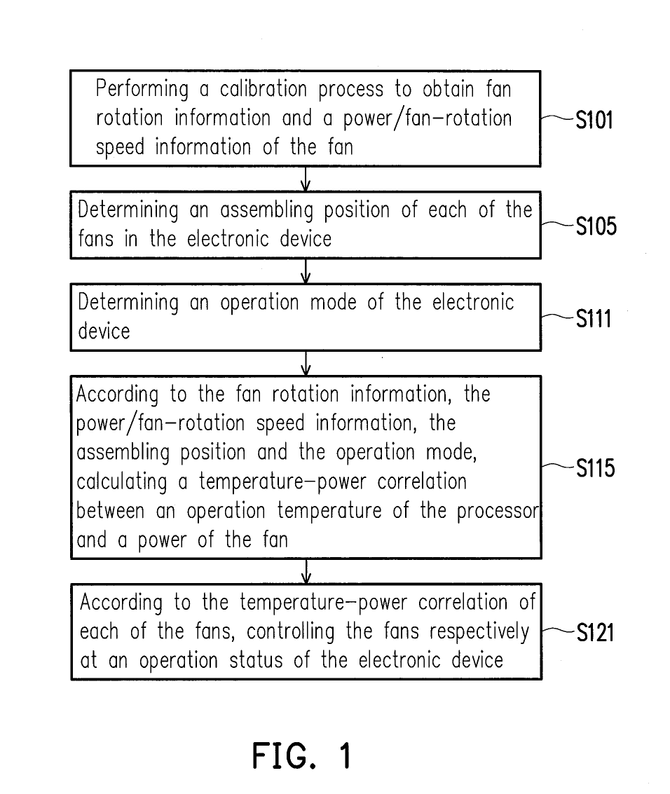

FIG. 1 is a flow chart showing a fan controlling method according to one embodiment of the present disclosure. The fan controlling method of the present embodiment is used by an electronic device. That is, the method of the present embodiment is used by an electronic device to control fan cluster having at least one fan within the electronic device. This electronic device can be, for example, a personal computer or a terminal server. Moreover, the electronic device further comprises a processor. As shown in FIG. 1, in the step S101, for each of the fans in the fan cluster, a calibration process is performed to obtain fan information of each of the fans and the power/fan-rotation speed information of each of the fans. Each of the fans corresponds to a rotation-starting-point power (i.e. the power of the external power applied on the fan while the fan is starting to rotate), a starting-point-rotation speed and a stop-point power (i.e. the power of the external power applied on the fan while the fan stops rotating). In other words, a gradient change voltage or a linear change voltage is applied onto each of the fans in the fan cluster to obtain the fan rotation speeds under different voltages, the rotation-starting-point powers under different voltages, the starting-point-rotation speeds under different voltages and the stop-point powers under different voltages.

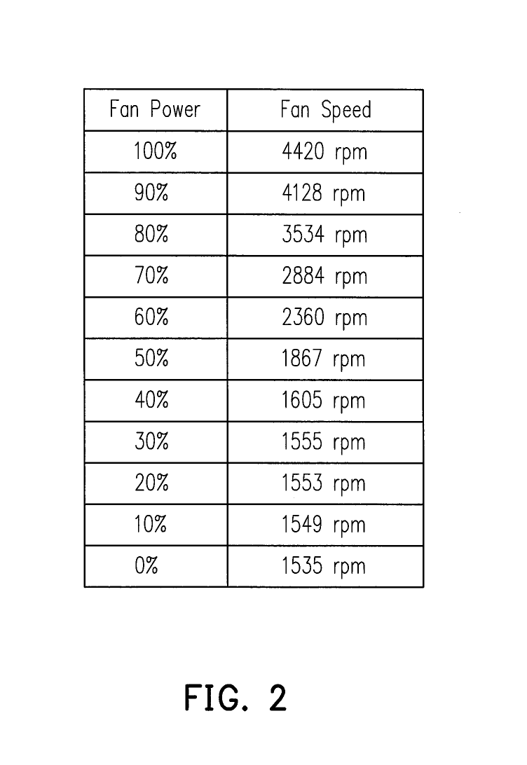

FIG. 2 is a correlation table showing power/fan-rotation speed information obtained from a calibration process according to one embodiment of the present disclosure. As shown in FIG. 2, in the present embodiment, the change of the fan rotation speed of the single fan under different external power source is obtained by applying the power which is changed from zero percent to 100 percent on the single fan.

The maximum rotation speed is about 4420 rpm. Further, while the power of the external power source is 0, the rotation speed is about 1535 rpm.

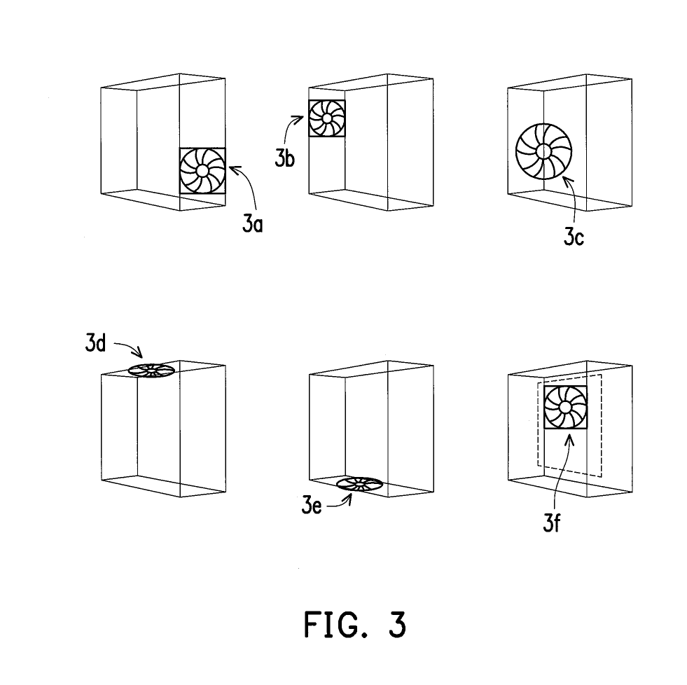

Then, as shown in FIG. 1, in the step S105, an assembling position of each of the fans in the electronic device is determined. For instance, the user can assign the assembling position to each of the fans in the electronic device. FIG. 3 is a schematic diagram showing assembling positions of fans in the electronic device. As shown in FIG. 3, using the operation surface of the electronic device as a basis, the assembling positions of the fans include the front position 3a, the back position 3b, the side position 3c, the upper position 3d, the bottom position 3e and the processor position 3f. That is, the user, according to the position exemplars mentioned above, can assign/set the assembling positions to the fans respectively.

In the step S111, an operation mode of the electronic device is determined. The operation mode includes a standard mode, a silence mode or a high-efficiency mode. In other words, according to the personal operation habit, the user can set the operation mode of the electronic device. For instance, when the user prefers the electronic device generating relatively small machine noises while operating, the operation mode of the electronic device can be set to be the silence mode. Alternatively, when the user prefer the electronic device executing the application with high operation performance, the operation mode of the electronic device can be set to be the high-efficiency mode so that the fans with relatively high operation efficiency provide the electronic device a more powerful heat dissipation efficiency.

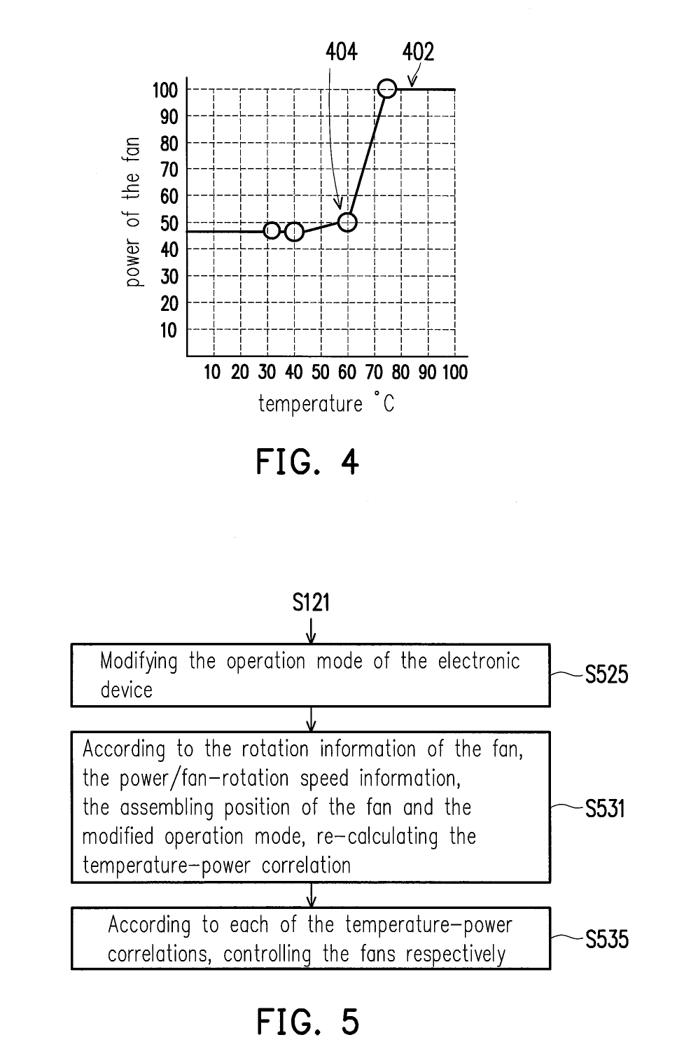

In the step S115, for each of the fans, according to the aforementioned fan rotation information, the power/fan-rotation speed information, the assembling position of the fan and the operation mode of the electronic device, a temperature-power correlation between an operation temperature of the processor and a power of the fan is calculated. FIG. 4 is a plot line diagram showing a temperature-power correlation between the power of a single fan and the operation temperature of the processor according to one embodiment of the present disclosure. As shown in FIG. 4, the temperature-power correlation corresponding to each of the fans can be, for example, a slope discontinuous correlation line 402 of the power of the corresponding fan versus the operation temperature of the processor. It should be noticed that the slope discontinuous correlation line comprises at least one slope turning point. The slop turning point in the discontinuous slope correlation line respectively corresponding to each of the fans represents a correlation between the power of the fan and the operation temperature of the processor while an operation efficiency of the processor is 50% (i.e. the slope turning point 404 shown in FIG. 4).

For instance, the slope of the correlation line, on which the operation temperature of the processor is below the temperature at the slope turning point 404 which corresponds to 50% operation efficiency of the processor, is smaller than the slope of the correlation line, on which the operation temperature of the processor is above the temperature at the slope turning point 404. In other words, when the operation temperature is lower than the slope turning point 404, the change of the power of the fan due to the change of the operation temperature is relatively small. That is, in response to the increase of the operation temperature, only small amount of change in the power of the fan can lead to the heat dissipation efficiency full filling the requirement of the user preferred operation mode of the electronic device.

When the operation temperature of the processor is higher than the slope turning point 404, the change of the power of the fan due to the change of the operation temperature is relatively large. That is, in response to the increase of the operation temperature, it is necessary to increase the amount of change in the power of the fan so that a relatively better heat dissipation efficiency can be achieved. More clearly, according to the operation feature (the fan rotation information of each of the fans and the power/fan-rotation speed information) of each fan, the assembling position of each fan and the operation mode of the electronic device, the power of each fan can be intelligently adjusted with the change of the operation temperature to meet the requirement of the user preferred operation mode of the electronic device. Hence, the power saving efficiency can be improved.

In the step S121, according to the temperature-power correlation of each of the fans, each of the fans is controlled at the operation status of the electronic device. That is, the processor, according to the received temperature detection information (such as the operation temperature of the processor detected by a temperature sensor) and according to the temperature-power correlation of each of the fans, automatically adjusts the power of each of the fans.

In the aforementioned embodiment, after the calibration process is performed (the step S101), the assembling position of each fan is determined (the step S05) and the operation mode of the electronic device is determined (the step S111), the temperature-power correlation between the operation temperature of the processor and the power of each fan can be calculated according to the information obtained from the previous executed steps. However, the present disclosure is not limited thereto. In another embodiment, after the calibration process is performed (the step S101) and the assembling position of each fan is determined (the step S105), according to the fan rotation information of each fan, the power/fan-rotation speed information of each fan and the assembling position of each fan, the temperature-power correlation between the operation temperature of the processor and the power of the fan can be preliminarily calculated. Then, after the operation mode of the electronic device is determined (the step S111), the temperature-power correlation between the operation temperature of the processor and the power of the fan is fine tuned according to the determined operation mode of the electronic device.

Moreover, in the aforementioned embodiment, when the assembling the electronic device, the user can assemble the fans in the any position within the electronic device by using the aforementioned fan controlling method to optimize the performance of each of the fans according to the personal requirements and the fan features. However, the present disclosure is not limited thereto. The present disclosure can be applied to re-control each of the fans when the user changes at least one fan or the operation mode of the electronic device.

FIG. 5 is a flow chart illustrating a fan controlling method according to another embodiment of the present disclosure. As shown in FIG. 5, under the situation that the electronic device controls each of the fans according to the temperature-power correlation corresponding to each of the fans (the step S121 shown in FIG. 1), the user changes/modifies the operation mode of the electronic device (the step S525). For instance, the operation mode is switched from the standard mode to the silence mode. In the step S531, for each of the fans in the electronic device, according to the fan rotation information, the power/fan-rotation speed information, the assembling position and the current operation mode (the modified operation mode), the temperature-power correlation is re-calculated. Then, in the step S535, according to the re-calculated temperature-power correlation of each of the fans, the fans are controlled respectively at an operation status of the electronic device.

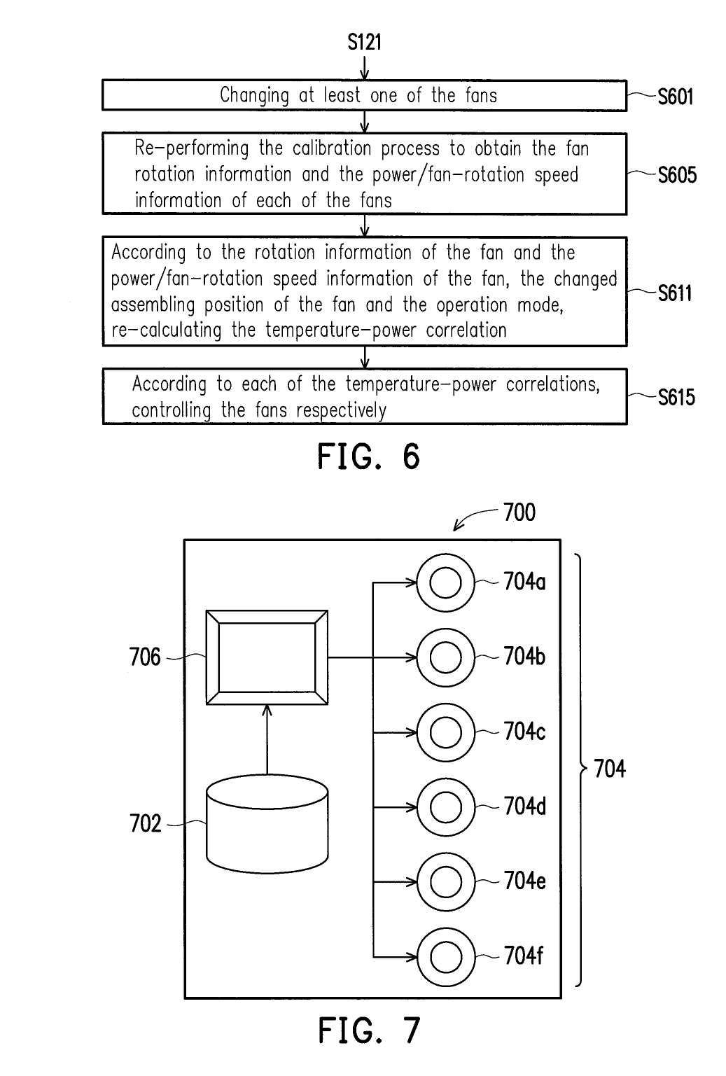

FIG. 6 is a flow chart illustrating a fan controlling method according to the other embodiment of the present disclosure. As shown in FIG. 6, in another embodiment, no matter under what kind of situation (such as the situation that the electronic device controls each of the fans according to the temperature-power correlation of each of the fans in the step S121 shown in FIG. 1), once the user changes at least one of the fans in the electronic device (the step S601), the calibration process is re-performed on the fans to obtain the fan rotation information of each of fans and the power/fan-rotation speed information of each of the fans (the step S605). Changing at least one of the fans in the electronic device can be, for example, removing at least one of the fans or replacing at least one of the fans.

Under the circumstance that the assembling positions of the fans are not changed and the operation mode of the electronic device is no longer changed, in the step S611, according to the re-obtained fan rotation information of each of the fans, the re-obtained power/fan-rotation speed information of each of the fans, previously determined assembling position of each of the fans and the previously determined operation mode of the electronic device, the temperature-power correlation between the operation temperature of the processor and the power of each of the fans is re-calculated. Thereafter, in the step S615, according to the temperature-power correlation corresponding to each of the fans, the fans are controlled respectively at an operation status of the electronic device.

FIG. 7 is a schematic diagram showing an electronic device according to one embodiment of the present disclosure. In the present embodiment, the aforementioned fan controlling method can be implemented by an electronic device executing a computer readable and writable program. As shown in FIG. 7, the electronic device 700 comprises a storage device 702, a fan cluster 704 (including at least one fan such as fans 704a, 704b, 704c, 704d, 704e and 704f), a processor 706. The storage device 702 stores a computer readable and writable program. The storage device 702 can be, for example, a non-volatile memory (including a flash memory). The processor 706 is coupled to the fan cluster 704 and the storage device 702 and executes a plurality of instructions of the computer readable and writable program so as to implement the fan controlling method (including the steps S101˜S121, S525˜S535 and S601˜S615) described in the previous embodiment. Since the steps for performing the fan controlling method are detailed in the previous embodiments and are not further described herein.

Altogether, in the present disclosure, each of the fans in the fan cluster are calibrated to obtain the fan individual operation feature (including fan rotation information and the power/fan-rotation speed information of the fan). Furthermore, by further taking the assembling position of each of the fans and the user preferred operation mode of the electronic device into account, the temperature-power correlation between the temperature of the processor and the power of each of the fans. According to the temperature-power correlation of each of the fans, the rotation status of each of the fans in the fan cluster is intelligently adjusted to provide the most adequate heat dissipation efficiency and the best power utilization while the electronic device is at the operation status. Therefore, the efficiency of the fan cluster is increased and the power consumption of the electronic device is decreased.

It will be apparent to those skilled in the art that various modifications and variations can be made to the structure of the present disclosure without departing from the scope or spirit of the invention. In view of the foregoing descriptions, it is intended that the present disclosure covers modifications and variations of this invention if they fall within the scope of the following claims and their equivalents.

What is claimed is:

1. A fan controlling method applied to an electronic device having at least a fan and a processor, the method comprising:
performing a calibration process on each of the at least fan to obtain fan rotation information and a power/fan-rotation speed information of the fan;
determining an assembling position of each of the at least fan in the electronic device;
determining an operation mode of the electronic device;
calculating a temperature-power correlation between an operation temperature of the processor and a power of the fan according to the fan rotation information, the power/fan-rotation speed information, the assembling position and the operation mode; and
controlling the at least fan at an operation status of the electronic device according to the temperature-power correlation of each of the at least fan.

2. The fan controlling method of claim 1, wherein the step of determining the assembling position of each of the at least fan in the electronic device comprises:
receiving a setting signal to set the assembling position of each of the at least fan in the electronic device.

3. The fan controlling method of claim 1, wherein the operation mode includes a standard mode, a silence mode or a high-efficiency mode.

4. The fan controlling method of claim 1, wherein the temperature-power correlation corresponding to each of the at least fan is a slope discontinuous correlation line of the power of the fan versus the operation temperature of the processor and the discontinuous correlation line comprises at least a slope turning point.

5. The fan controlling method of claim 4, wherein the at least slope turning point in the discontinuous slope correlation line respectively corresponding to each of the at least fan represents a correlation between the power of the fan and the operation temperature of the processor while an operation efficiency of the processor is 50%.

6. The fan controlling method of claim 1, further comprising:
modifying the operation mode of the electronic device;
re-calculating the temperature-power correlation on each of the at least fan according to the rotation information of the fan, the power/fan-rotation speed information, the assembling position of the fan and the modified operation mode; and
controlling the at least fan according to each of the temperature-power correlations.

7. The fan controlling method of claim 1, further comprising:
changing the assembling position of at least one of the at least fan;
re-performing the calibration process to obtain the fan rotation information and the power/fan-rotation speed information of each of the at least fan after the assembling position of the at least one of the at least fan is changed;
re-calculating the temperature-power correlation on each of the at least fan according to the rotation information of the fan and the power/fan-rotation speed information of the fan, the changed assembling position of the fan and the operation mode; and
controlling the at least fan according to each of the temperature-power correlations.

8. The fan controlling method of claim 7, wherein the step of changing the assembling position of at least one of the at least fan comprises removing at least one of the at least fan or replacing at least one of the at least fan.

9. The fan controlling method of claim 1, wherein the fan rotation information of each of the at least fan includes a rotation-starting-point power of the fan, a starting-point-rotation speed of the fan and a stop-point power of the fan.

10. An electronic device, comprising:
a storage device storing a computer readable and writable program;
at least a fan;
a processor coupled to the at least fan and the storage device and executing a plurality of instructions of the computer readable and writable program, wherein the instructions comprise:
performing a calibration process on each of the at least fan, to obtain fan rotation information and a power/fan-rotation speed information of the fan;
reading an assembling position of each of the at least fan in the electronic device;
reading an operation mode in the electronic device;
calculating a temperature-power correlation between an operation temperature of the processor and a power of the fan according to the rotation information of the fan, the power/fan-rotation speed information of the fan, the assembling position of the fan and the operation mode; and
controlling the at least fan according to the temperature-power correlation of each of the at least fan.

11. The electronic device of claim 10, wherein the instruction of reading the assembling position of each of the at least fan in the electronic device comprises:
receiving a setting signal to set the assembling position of each of the at least fan in the electronic device.

12. The electronic device of claim 10, wherein the operation mode includes a standard mode, a silence mode or a high-efficiency mode.

13. The electronic device of claim 10, wherein the temperature-power correlation corresponding to each of the at least fan is a slope discontinuous correlation line of the power of the fan versus the operation temperature of the processor and the discontinuous correlation line comprises at least a slope turning point.

14. The electronic device of claim 13, wherein the at least slope turning point in the discontinuous slope correlation line respectively corresponding to each of the at least fan represents a correlation between the power of the fan and the operation temperature of the processor while an operation efficiency of the processor is 50%.

15. The electronic device of claim 10, wherein the instructions further comprises:
modifying the operation mode of the electronic device;
re-calculating the temperature-power correlation on each of the at least fan according to the rotation information of the fan, the power/fan-rotation speed information, the assembling position of the fan and the modified operation mode; and
controlling the at least fan according to each of the temperature-power correlations.

16. The electronic device of claim 10, wherein the instructions further comprises:
changing the assembling position of at least one of the at least fan;
re-performing the calibration process to obtain the fan rotation information and the power/fan-rotation speed information of each of the at least fan after the assembling position of the at least one of the at least fan is changed;
re-calculating the temperature-power correlation on each of the at least fan according to the rotation information of the fan and the power/fan-rotation speed information of the fan, the changed assembling position of the fan and the operation mode; and
controlling the at least fan according to each of the temperature-power correlations.

17. The electronic device of claim 16, wherein the instruction of changing the assembling position of at least one of the at least fan comprises removing at least one of the at least fan or replacing at least one of the at least fan.

18. The electronic device of claim 10, wherein the fan rotation information of each of the at least fan includes a rotation-starting-point power of the fan, a starting-point-rotation speed of the fan and a stop-point power of the fan.
